(19) United States
(12) Patent Application Publication
(10) Pub. No.: US 2025/0062237 A1
(43) Pub. Date: Feb. 20, 2025

(54) SEMICONDUCTOR PACKAGE

(71) Applicant: SAMSUNG ELECTRONICS CO., LTD., SUWON-SI (KR)

(72) Inventors: Kwangsoo Kim, Suwon-si (KR); Hyunsoo Chung, Suwon-si (KR); Jungul Hwang, Suwon-si (KR)

(21) Appl. No.: 18/648,683

(22) Filed: Apr. 29, 2024

(30) Foreign Application Priority Data
Aug. 18, 2023 (KR) 10-2023-0108545

(51) Int. Cl. H01L 23/538; H01L 23/00; H01L 23/31; H01L 23/498; H01L 25/10

(52) U.S. Cl. CPC H01L 23/5385; H01L 23/3128; H01L 23/49811; H01L 24/16; H01L 24/48; H01L 25/105; H01L 2224/16225; H01L 2224/48225

(57) ABSTRACT

Provided is a semiconductor package including a first redistribution layer, a first semiconductor chip disposed on the first redistribution layer, a circuit board disposed between the first redistribution layer and the first semiconductor chip, bonding wires connecting the first semiconductor chip and the circuit board to each other, a second redistribution layer disposed on the first semiconductor chip, a second semiconductor chip disposed on the second redistribution layer, and conductive posts connecting the first redistribution layer and the second redistribution layer to each other.

### CROSS-REFERENCE TO RELATED APPLICATION

This application is based on and claims priority under 35 U.S.C. § 119 to Korean Patent Application No. 10-2023-0108545, filed on Aug. 18, 2023, in the Korean Intellectual Property Office, the disclosure of which is incorporated by reference herein in its entirety.

### BACKGROUND

### 1. Technical Field

The inventive concept relates to a semiconductor package, and more particularly, to a semiconductor package including an upper chip and a lower chip having respective connections to a first redistribution layer.

### 2. Discussion of Related Art

In a semiconductor package, a redistribution layer may electrically connect a semiconductor chip to a device or a printed circuit board. The semiconductor chip may be packaged by using the redistribution layer. The packaging method can be used to manufacture the semiconductor package having a small planar area, a thin thickness, a fast speed, and a high bandwidth.

### SUMMARY

The inventive concept provides a semiconductor package including an upper chip and a lower chip having respective connections to a first redistribution layer, wherein the semiconductor packages has improved performance and reliability.

According to an aspect of the inventive concept, there is provided a semiconductor package including a first redistribution layer, a first semiconductor chip disposed on the first redistribution layer, a circuit board disposed between the first redistribution layer and the first semiconductor chip, a plurality of bonding wires connecting the first semiconductor chip with the circuit board, a second redistribution layer disposed on the first semiconductor chip, a second semiconductor chip disposed on the second redistribution layer, and a plurality of conductive posts connecting the first redistribution layer with the second redistribution layer.

According to another aspect of the inventive concept, there is provided a semiconductor package including a lower structure, an upper structure stacked on the lower structure, and a plurality of external connection terminals disposed under the lower structure, wherein the lower structure comprises a first redistribution layer, a first semiconductor chip disposed on the first redistribution layer, a plurality of bonding wires connecting the first semiconductor chip with the first redistribution layer, and a plurality of conductive posts connecting the first redistribution layer with the upper structure, wherein the upper structure comprises a second redistribution layer disposed on the lower structure, a second semiconductor chip disposed on the second redistribution layer, and a plurality of bumps disposed between the second semiconductor chip and the second redistribution layer.

According to another aspect of the inventive concept, there is provided a semiconductor package including a first redistribution layer, a first semiconductor chip and a second semiconductor chip disposed on the first redistribution layer to be spaced apart from each other in a first direction, a first circuit board disposed between the first redistribution layer and the first semiconductor chip, a second circuit board disposed between the first redistribution layer and the second semiconductor chip, first bonding wires connecting the first semiconductor chip with the first circuit board, second bonding wires connecting the second semiconductor chip with the second circuit board, a plurality of first bumps disposed on the first redistribution layer, wherein the first circuit board is disposed on a first set of the plurality of first bumps and the second circuit board is disposed on a second set of the plurality of first bumps, a second redistribution layer disposed on the first semiconductor chip, a third semiconductor chip and a fourth semiconductor chip disposed on the second redistribution layer to be spaced apart from each other in the first direction, a plurality of second bumps disposed on the second redistribution layer, wherein the third semiconductor chip is disposed on a first set of the plurality of second bumps and the fourth semiconductor chip is disposed on a second set of the plurality of second bumps, a plurality of conductive posts connecting the first redistribution layer with the second redistribution layer, and a plurality of external connection terminals disposed under the first redistribution layer, wherein the first semiconductor chip is connected to the first redistribution layer through the first bonding wires and the first circuit board, and the third semiconductor chip is attached to the second redistribution layer in a flip-chip structure.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view illustrating a semiconductor package according to an embodiment;

FIG. 2, FIG. 3, and FIG. 4 are cross-sectional views illustrating semiconductor packages according to some embodiments;

FIG. 5 and FIG. 6 are cross-sectional views illustrating semiconductor packages according to some embodiments;

FIG. 7 is a cross-sectional view illustrating a semiconductor package according to an embodiment;

FIGS. 8A to 8H are cross-sectional views for explaining a method of manufacturing a semiconductor package according to some embodiments;

FIG. 9A and FIG. 9B are cross-sectional views for explaining a method of manufacturing a semiconductor package according to some embodiments;

FIG. 10A and FIG. 10B are cross-sectional views for explaining a method of manufacturing a semiconductor package according to some embodiments; and

FIGS. 11A to 11F are cross-sectional views for explaining a method of manufacturing a semiconductor package according to some embodiments.

### DETAILED DESCRIPTION

Hereinafter, embodiments of the inventive concept will be described in detail with reference to the accompanying drawings. However, the inventive concept is not intended to be limited to examples described below and may be embodied in various other forms. Embodiments are provided to sufficiently convey the scope of this inventive concept to those skilled in the art.

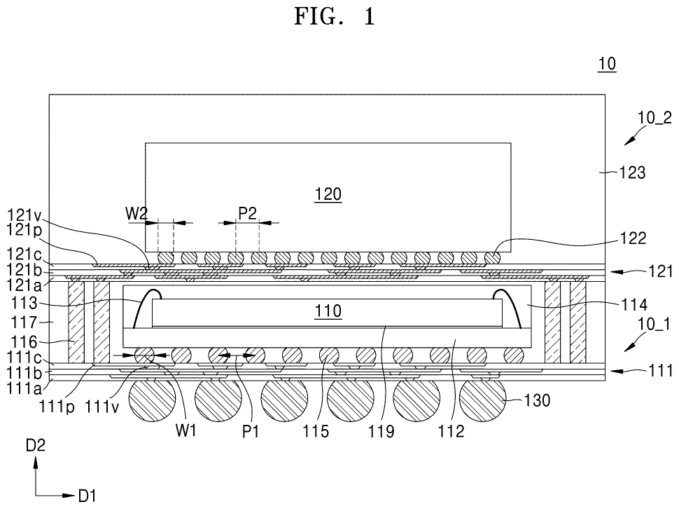

FIG. 1 is a cross-sectional view illustrating a first semiconductor package 10 according to an embodiment.

Referring to FIG. 1, the first semiconductor package 10 may include a lower structure 10_1 and an upper structure 10_2 stacked vertically. Specifically, the upper structure 10_2 may be stacked on the lower structure 10_1 in the second direction D2. The lower structure 10_1 may include a first semiconductor chip 110. The upper structure 10_2 may include a second semiconductor chip 120.

In some embodiments, the lower structure 10_1 may include the first semiconductor chip 110, a first redistribution layer 111, a carrier such as a circuit board 112 or a lead frame, a plurality of bonding wires 113, a plurality of first bumps 115, and a plurality of conductive posts 116.

In some embodiments, the first semiconductor chip 110 may be disposed on the first redistribution layer 111. Specifically, the first semiconductor chip 110 may be disposed on the circuit board 112 and mounted on the first redistribution layer 111.

In some embodiments, the first redistribution layer 111 may include a plurality of redistribution insulating layers 111a, 111b, and 111c, a plurality of redistribution pads 111p, and a plurality of redistribution vias 111v. The plurality of redistribution pads 111p may be disposed in the plurality of redistribution insulating layers 111a, 111b, and 111c. The plurality of redistribution vias 111v may contact the plurality of redistribution pads 111p in the plurality of redistribution insulating layers 111a, 111b, and 111c. The first redistribution layer 111 may include a redistribution layer.

In some embodiments, the first redistribution layer 111 may provide an electrical path connecting the first semiconductor chip 110 with a plurality of external connection terminals 130. The first redistribution layer 111 may provide an electrical path connecting the circuit board 112 with the external connection terminals 130.

In some embodiments, the circuit board 112 may be disposed between the first semiconductor chip 110 and the first redistribution layer 111. The circuit board 112 may provide an electrical path connecting the first semiconductor chip 110 with the first redistribution layer 111. The circuit board 112 may be a printed circuit board (PCB). The circuit board 112 may be a type of carrier. In an embodiment, the circuit board 112 may be replaced by another type of carrier, such as a lead frame.

In some embodiments, an adhesive layer 119 may be disposed between the first semiconductor chip 110 and the circuit board 112. For example, the first semiconductor chip 110 may be attached to the circuit board 112 by the adhesive layer 119. In some embodiments, the adhesive layer 119 may include a die attach film (DAF).

In some embodiments, the first semiconductor chip 110 may be connected to the circuit board 112 by bonding wires 113. Specifically, the bonding wires 113 may provide an electrical path connecting the first semiconductor chip 110 with the circuit board 112. For example, an electrical signal generated by the first semiconductor chip 110 may be transmitted to the circuit board 112 through the bonding wires 113. The bonding wires 113 may be connected to an upper surface of the first semiconductor chip 110 and connected to an upper surface of the circuit board 112.

In some embodiments, an intermediate molding layer 114 may be disposed on the circuit board 112, and may encapsulate the first semiconductor chip 110, the adhesive layer 119, and the bonding wires 113. Specifically, the intermediate molding layer 114 may surround the first semiconductor chip 110, the adhesive layer 119, and the bonding wires 113 in the first direction D1. For example, the intermediate molding layer 114 may include an epoxy resin, a silicone resin, or a combination thereof. For example, the intermediate molding layer 114 may include an epoxy mold compound (EMC).

In some embodiments, a plurality of first bumps 115 may be disposed between the circuit board 112 and the first redistribution layer 111. In some embodiments, the plurality of first bumps 115 may be attached to a lower surface of the circuit board 112. The first bumps 115 may provide an electrical path connecting the circuit board 112 with the first redistribution layer 111. The first bumps 115 may provide an electrical path connecting the first semiconductor chip 110 with the first redistribution layer 111. The plurality of first bumps 115 may include a conductive material. For example, the plurality of first bumps 115 may include tin (Sn), lead (Pb), silver (Ag), copper (Cu), or a combination thereof.

In some embodiments, the electrical signal generated by the first semiconductor chip 110 may be transmitted to the first redistribution layer 111 through the bonding wires 113. Specifically, the electrical signal generated by the first semiconductor chip 110 may be transmitted to the circuit board 112 through the bonding wires 113. Thereafter, the electrical signal transmitted to the circuit board 112 may be transmitted to the first redistribution layer 111 through the plurality of first bumps 115. The electrical signal generated by the first semiconductor chip 110 and transmitted to the first redistribution layer 111 may be transmitted to the external connection terminals 130 through the plurality of redistribution pads 111p and the plurality of redistribution vias 111v disposed in the first redistribution layer 111.

In some embodiments, a plurality of conductive posts 116 may be disposed between the lower structure 10_1 and the upper structure 10_2. Specifically, the conductive posts 116 may connect the lower structure 10_1 with the upper structure 10_2. Specifically, the conductive posts 116 may be disposed between the first redistribution layer 111 and the second redistribution layer 121. The conductive posts 116 may connect the first redistribution layer 111 with the second redistribution layer 121. The conductive posts 116 may connect an upper surface of the first redistribution layer 111 with a lower surface of the second redistribution layer 121. Specifically, the conductive posts 116 may provide an electrical path connecting the first redistribution layer 111 with the second redistribution layer 121.

The conductive posts 116 may each include a conductive material. For example, the conductive posts 116 may include copper (Cu), gold (Au), silver (Ag), nickel (Ni), tungsten (W), aluminum (Al), or a combination thereof. In some embodiments, the conductive posts 116 may each further include a barrier material. The barrier material may prevent the conductive material from diffusing out of the conductive posts 116. The barrier material may include, for example, titanium (Ti), tantalum (Ta), titanium nitride (TiN), tantalum nitride (TaN), or a combination thereof.

In some embodiments, the lower molding layer 117 may be disposed on the first redistribution layer 111, and may encapsulate the first semiconductor chip 110 and the conductive posts 116. Specifically, the lower molding layer 117 may encapsulate the intermediate molding layer 114, the circuit board 112, the plurality of first bumps 115, the conductive posts 116, and the first redistribution layer 111. In some embodiments, the lower molding layer 117 may form the lower structure 10_1 by encapsulating the first semiconductor chip 110, the adhesive layer 119, the circuit board 112, the bonding wires 113, the plurality of first bumps 115, and the conductive posts 116, while being disposed on the first redistribution layer 111. In some embodiments, the lower molding layer 117 may surround the intermediate molding layer 114, the plurality of first bumps 115, and the conductive posts 116 in a first direction D1.

In some embodiments, the lower molding layer 117 may include a portion for encapsulating the plurality of first bumps 115 disposed between the circuit board 112 and the first redistribution layer 111. Specifically, the lower molding layer 117 may include a portion disposed between the plurality of first bumps 115 disposed between the circuit board 112 and the first redistribution layer 111, thereby encapsulating the plurality of first bumps 115.

The lower molding layer 117 may include, for example, an epoxy resin, a silicone resin, or a combination thereof. For example, the lower molding layer 117 may include an epoxy mold compound. In some embodiments, the lower molding layer 117 may include the same material as the intermediate molding layer 114. In some embodiments, the lower molding layer 117 may include a material different from that of the intermediate molding layer 114.

In some embodiments, the upper structure 10_2 may be disposed on the lower structure 10_1. In some embodiments, the upper structure 10_2 may include a second semiconductor chip 120, a second redistribution layer 121, and a plurality of second bumps 122.

In some embodiments, the second redistribution layer 121 may be disposed on the first redistribution layer 111. Specifically, the second redistribution layer 121 may be disposed on the lower molding layer 117 that encapsulates the first semiconductor chip 110, the circuit board 112, and the like.

In some embodiments, the second redistribution layer 121 may include a plurality of redistribution insulating layers 121a, 121b, and 121c, a plurality of redistribution pads 121p, and a plurality of redistribution vias 121v. The plurality of redistribution pads 121p may be disposed in the plurality of redistribution insulating layers 121a, 121b, and 121c. The plurality of redistribution vias 121v may contact the plurality of redistribution pads 121p in the plurality of redistribution insulating layers 121a, 121b, and 121c. The second redistribution layer 121 may include a redistribution layer.

In some embodiments, the second semiconductor chip 120 may be disposed on the second redistribution layer 121. The second semiconductor chip 120 may be mounted on the second redistribution layer 121 without a circuit board disposed therebetween.

In some embodiments, the second semiconductor chip 120 may be mounted on the second redistribution layer 121 in a flip-chip structure. For example, the second semiconductor chip 120 may have a first surface and a second surface. The first surface may be an active surface and the second surface may be an inactive surface opposite to the first surface. The active surface of the second semiconductor chip 120 may face the second redistribution layer 121.

In some embodiments, the second redistribution layer 121 may provide an electrical path connecting the second semiconductor chip 120 with the external connection terminals 130. The second redistribution layer 121 may provide an electrical path connecting the second semiconductor chip 120 with the first redistribution layer 111.

In some embodiments, a plurality of second bumps 122 may be disposed between the second semiconductor chip 120 and the second redistribution layer 121. In some embodiments, the plurality of second bumps 122 may be attached to the second semiconductor chip 120. The plurality of second bumps 122 may provide an electrical path connecting the second semiconductor chip 120 with the second redistribution layer 121. The plurality of second bumps 122 may include a conductive material. For example, the plurality of second bumps 122 may include tin (Sn), lead (Pb), silver (Ag), copper (Cu), or a combination thereof.

In some embodiments, the plurality of first bumps 115 and the plurality of second bumps 122 may be of different types. For example, as described above, the plurality of first bumps 115 may be attached to a lower surface of the circuit board 112, and the plurality of second bumps 122 may be attached to a lower surface of the second semiconductor chip 120. As described above, the lower surface of the second semiconductor chip 120 may be an active surface.

In some embodiments, sizes of the plurality of first bumps 115 may be different from sizes of the plurality of second bumps 122. Specifically, the width W1 of each of the plurality of first bumps 115 in the first direction D1 may be greater than the width W2 of each of the plurality of second bumps 122 in the first direction D1. Specifically, the height of each of the plurality of first bumps 115 in the second direction D2 may be greater than the height of each of the plurality of second bumps 122 in the second direction D2. However, embodiments are not limited thereto, and other implementations are contemplated. For example, the width W1 of each of the plurality of first bumps 115 in the first direction D1 may be greater than the width W2 of each of the plurality of second bumps 122 in the first direction D1, and the height of each of the plurality of first bumps 115 in the second direction D2 and the height of each of the plurality of second bumps 122 in the second direction D2 may be the same.

In some embodiments, a pitch between adjacent first bumps of the plurality of first bumps 115 and a pitch between adjacent second bumps of the plurality of second bumps 122 may be different from each other. Specifically, the pitch PI between the adjacent first bumps of the plurality of first bumps 115 in the first direction D1 may be greater than the pitch P2 between the adjacent second bumps of the plurality of second bumps 122 in the first direction D1. However, embodiments are not limited thereto, and other implementations are contemplated.

In some embodiments, the upper molding layer 123 may be disposed on the second redistribution layer 121 and encapsulate the second semiconductor chip 120 and the plurality of second bumps 122. Specifically, the upper molding layer 123 may surround the second semiconductor chip 120 and the plurality of second bumps 122 in the first direction D1. In some embodiments, the upper molding layer 123 may include a portion for encapsulating the plurality of second bumps 122 between the second semiconductor chip 120 and the second redistribution layer 121. Specifically, the upper molding layer 123 may include a portion disposed between the plurality of second bumps 122 between the second semiconductor chip 120 and the second redistribution layer 121 to thereby encapsulate the plurality of second bumps 122.

The upper molding layer 123 may include, for example, an epoxy resin, a silicone resin, or a combination thereof. For example, the upper molding layer 123 may include an epoxy mold compound. In some embodiments, the upper molding layer 123 may include the same material as the intermediate molding layer 114 and/or the lower molding layer 117. In some embodiments, the upper molding layer 123 may include a different material from the intermediate molding layer 114 and/or the lower molding layer 117.

In some embodiments, the electrical signal of the second semiconductor chip 120 may be transmitted to the second redistribution layer 121 through the plurality of second bumps 122. Thereafter, the electrical signal transmitted to the second redistribution layer 121 may be transmitted to the conductive posts 116 through the plurality of redistribution pads 121p and the plurality of redistribution vias 121v formed in the second redistribution layer 121, and the electrical signal may be transmitted to the first redistribution layer 111 through the conductive posts 116. The electrical signal of the second semiconductor chip 120 transmitted to the first redistribution layer 111 may be transmitted to the external connection terminals 130.

In some embodiments, the external connection terminals 130 may be located on a bottom surface of the first redistribution layer 111 of the lower structure 10_1. The external connection terminals 130 may include, for example, a conductive material such as tin (Sn), lead (Pb), silver (Ag), copper (Cu), or a combination thereof. The external connection terminals 130 may be formed using, for example, solder balls. The external connection terminals 130 may connect the first semiconductor package 10 to, for example, a circuit board, another semiconductor package, an interposer, or a combination thereof.

In some embodiments, the first semiconductor chip 110 and/or the second semiconductor chip 120 may include a graphics double data rate (GDDR) chip. In some embodiments, the first semiconductor chip 110 and the second semiconductor chip 120 may be the same type of semiconductor chips. In some embodiments, the first semiconductor chip 110 and the second semiconductor chip 120 may be different types of semiconductor chips.

According to embodiments of the inventive concept, since the first semiconductor chip 110 of the lower structure 10_1 may be connected to the first redistribution layer 111 through the bonding wires 113 and the circuit board 112, defects that may occur due to bumps attached directly to the first semiconductor chip 110 may be avoided or eliminated.

According to embodiments of the inventive concept, the second semiconductor chip 120 of the upper structure 10_2 may be attached to the second redistribution layer 121 in a flip-chip structure, and the first semiconductor chip 110 of the lower structure 10_1 may be connected to the first redistribution layer 111 through the bonding wires 113. Accordingly, in the first semiconductor package 10 according to embodiments of the inventive concept, a difference in length between a path of the second semiconductor chip 120 of the upper structure 10_2 to the external connection terminals 130 and a path of the first semiconductor chip 110 of the lower structure 10_1 to the external connection terminals 130 may be reduced or eliminated, thereby improving signal characteristics. For example, the path of the second semiconductor chip 120 of the upper structure 10_2 to the external connection terminals 130 and the path of the first semiconductor chip 110 of the lower structure 10_1 to the external connection terminals 130 may be equal. For example, a length of the bonding wires 113, a height of plurality of first bumps 115, a height of the plurality of second bumps 122, etc., may be configured to reduce a difference in the lengths of electric paths of the first semiconductor package 10.

That is, according to embodiments according to the inventive concept, the first semiconductor package 10 with improved performance and reliability may be provided.

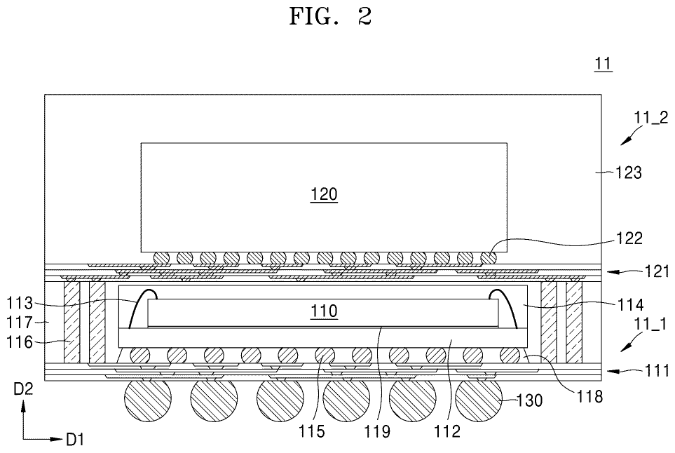

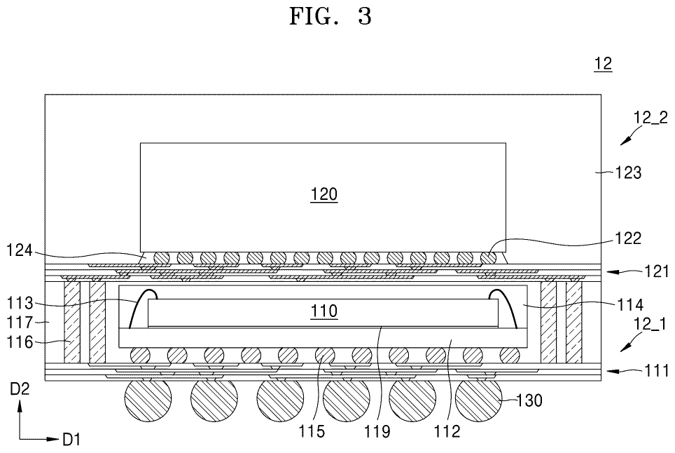

FIG. 2, FIG. 3, and FIG. 4 are cross-sectional views illustrating a second semiconductor package 11, a third semiconductor package 12, and a fourth semiconductor package 13, respectively, according to embodiments. In comparison with the first semiconductor package 10 described with reference to FIG. 1, differences will be mainly described.

Referring to FIG. 2, the second semiconductor package 11 may include a lower structure 11_1 and an upper structure 11_2 stacked vertically. Specifically, the upper structure 11_2 may be stacked on the lower structure 11_1 in the second direction D2. The lower structure 11_1 may include a first semiconductor chip 110. The upper structure 11_2 may include a second semiconductor chip 120.

In some embodiments, the second semiconductor package 11 may further include a first underfill layer 118 disposed between the circuit board 112 and the first redistribution layer 111. Specifically, the second semiconductor package 11 may further include the first underfill layer 118 disposed between the circuit board 112 and the first redistribution layer 111 of the lower structure 11_1.

In some embodiments, the first underfill layer 118 may encapsulate a plurality of first bumps 115 disposed between the circuit board 112 and the first redistribution layer 111. Specifically, the first underfill layer 118 may include a portion disposed between the plurality of first bumps 115 between the circuit board 112 and the first redistribution layer 111 that encapsulates the plurality of first bumps 115.

The lower molding layer 117 of the second semiconductor package 11 of FIG. 2 may not be disposed between the circuit board 112 and the first redistribution layer 111, and the first underfill layer 118, separate from the lower molding layer 117, may encapsulate a plurality of first bumps 115. Even when the lower molding layer 117 may contact a portion of a lower surface of the circuit board 112, for example, around a periphery of an area defined by the plurality of first bumps 115, the first underfill layer 118 may encapsulate the plurality of first bumps 115, and the lower molding layer 117 may be disposed on a side surface of the first underfill layer 118.

The first underfill layer 118 may include, for example, a polymer, an epoxy resin, or a combination thereof. For example, the first underfill layer 118 may include a material different from that of the lower molding layer 117.

Referring to FIG. 3, the third semiconductor package 12 may include a lower structure 12_1 and an upper structure 12_2 stacked vertically. Specifically, the upper structure 12_2 may be stacked on the lower structure 12_1 in the second direction D2. The lower structure 12_1 may include a first semiconductor chip 110. The upper structure 12_2 may include a second semiconductor chip 120.

In some embodiments, the third semiconductor package 12 may further include a second underfill layer 124. The second underfill layer 124 may be disposed between the second semiconductor chip 120 and the second redistribution layer 121. Specifically, the third semiconductor package 12 may further include a second underfill layer 124 disposed between the second semiconductor chip 120 and the second redistribution layer 121 of the upper structure 12_2.

In some embodiments, the second underfill layer 124 may encapsulate a plurality of second bumps 122 disposed between the second semiconductor chip 120 and the second redistribution layer 121. Specifically, the second underfill layer 124 may include a portion disposed between the plurality of second bumps 122 between the second semiconductor chip 120 and the second redistribution layer 121 to encapsulate the plurality of second bumps 122.

The upper molding layer 123 of the third semiconductor package 12 of FIG. 3 may not be disposed between the second semiconductor chip 120 and the second redistribution layer 121, and the second underfill layer 124 may be disposed to encapsulate the plurality of second bumps 122. Even when the upper molding layer 123 may contact a portion of a lower surface of the second semiconductor chip 120, for example, around a periphery of an area defined by the plurality of second bumps 122, the second underfill layer 124 may encapsulate the plurality of second bumps 122, and the upper molding layer 123 may be disposed on a side surface of the second underfill layer 124.

The second underfill layer 124 may include, for example, a polymer, an epoxy resin, or a combination thereof. For example, the second underfill layer 124 may include a material different from that of the upper molding layer 123.

Referring to FIG. 4, the fourth semiconductor package 13 may include a lower structure 13_1 and an upper structure 13_2 stacked vertically. Specifically, the upper structure 13_2 may be stacked on the lower structure 13_1 in the second direction D2. The lower structure 13_1 may include a first semiconductor chip 110. The upper structure 13_2 may include a second semiconductor chip 120.

In some embodiments, the fourth semiconductor package 13 may further include the first underfill layer 118 disposed between the circuit board 112 and the first redistribution layer 111, and the second underfill layer 124 disposed between the second semiconductor chip 120 and the second redistribution layer 121. Specifically, the fourth semiconductor package 13 may further include the first underfill layer 118 disposed between the circuit board 112 and the first redistribution layer 111 of the lower structure 13_1, and the second underfill layer 124 disposed between the second semiconductor chip 120 and the second redistribution layer 121 of the upper structure 13_2. A description of the first underfill layer 118 may be further understood by referring to FIG. 2 and a description of the second underfill layer 124 may be further understood by referring to FIG. 3.

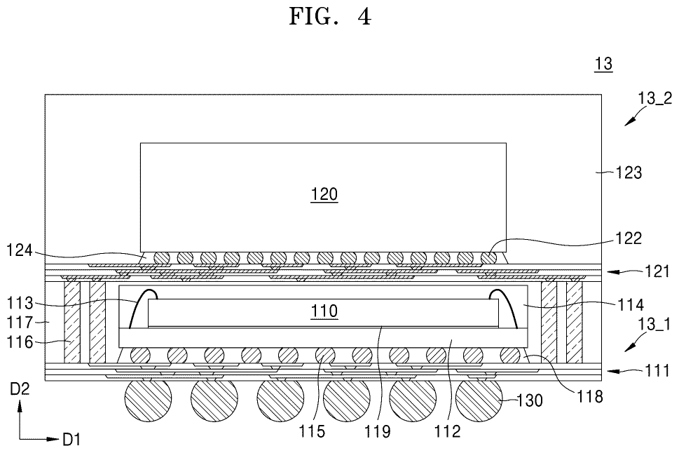

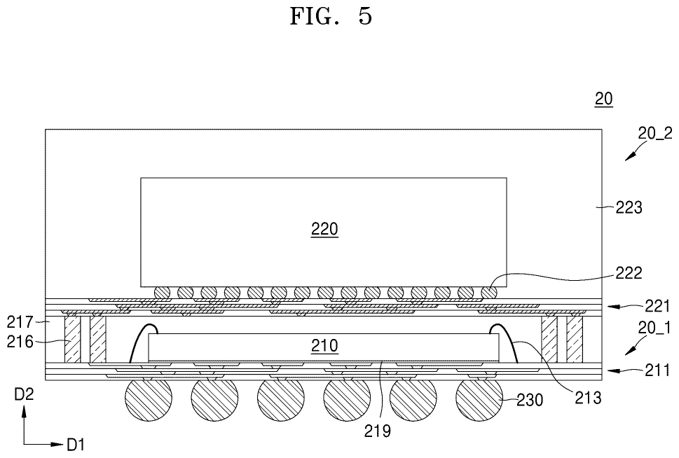

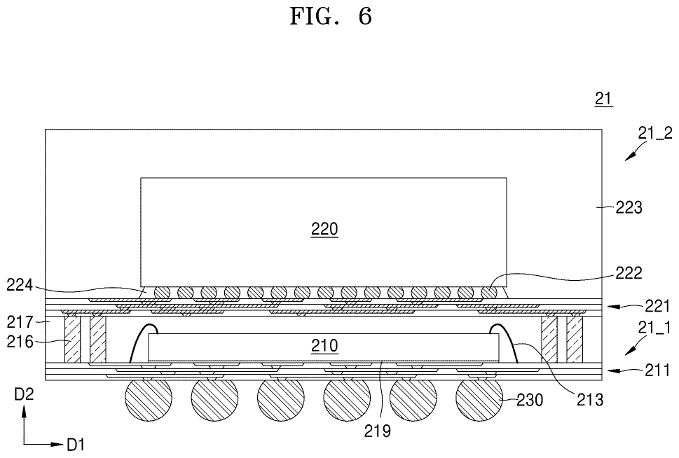

FIG. 5 and FIG. 6 are cross-sectional views illustrating a fifth semiconductor package 20 and a sixth semiconductor package 21, respectively, according to some embodiments.

Referring to FIG. 5, the fifth semiconductor package 20 may include a lower structure 20_1 and an upper structure 20_2 stacked vertically. The upper structure 20_2 may be stacked on the lower structure 20_1 in the second direction D2. The lower structure 20_1 may include the first semiconductor chip 210. The upper structure 20_2 may include the second semiconductor chip 220. In comparison with the semiconductor package 10 described with reference to FIG. 1, differences will be mainly described.

In some embodiments, the lower structure 20_1 may include a first semiconductor chip 210, a first redistribution layer 211, a plurality of bonding wires 213, and a plurality of conductive posts 216. The lower structure 20_1 of the fifth semiconductor package 20 may not have a circuit board or a plurality of bumps disposed between the first semiconductor chip 210 and the first redistribution layer 211.

In some embodiments, the first semiconductor chip 210 may be disposed on the first redistribution layer 211. The first semiconductor chip 210 of the fifth semiconductor package 20 may be directly mounted on the first redistribution layer 211.

In some embodiments, the first redistribution layer 211 may be understood by referring to the description of the first redistribution layer 111 of FIG. 1. In some embodiments, the first redistribution layer 211 may provide an electrical path connecting the first semiconductor chip 210 with external connection terminals 230.

In some embodiments, an adhesive layer 219 may be disposed between the first semiconductor chip 210 and the first redistribution layer 211. For example, the first semiconductor chip 210 may be adhered to an upper surface of the first redistribution layer 211 by the adhesive layer 219. In some embodiments, the adhesive layer 219 may include a DAF.

In some embodiments, the first semiconductor chip 210 may be connected to the first redistribution layer 211 by bonding wires 213. Specifically, the bonding wires 213 may provide an electrical path connecting the first semiconductor chip 210 with the first redistribution layer 211. For example, the electrical signal generated by the first semiconductor chip 210 may be transmitted to the first redistribution layer 211 through the bonding wires 213. For example, the first semiconductor chip 210 may have a first surface and a second surface. The first surface may be an active surface and the second surface may be an inactive surface opposite to the first surface. For example, the inactive surface may face the first redistribution layer 211 and the bonding wires 213 may be connected on the active surface.

In some embodiments, the electrical signal of the first semiconductor chip 210 of the fifth semiconductor package 20 of FIG. 5 may be directly transmitted to the first redistribution layer 211 through the bonding wires 213. Subsequently, the electrical signal of the first semiconductor chip 210 transmitted to the first redistribution layer 211 may be transmitted to the external connection terminals 230 through a plurality of redistribution pads and a plurality of redistribution vias formed in the first redistribution layer 211.

In some embodiments, conductive posts 216 may be disposed between the lower structure 20_1 and the upper structure 20_2. Specifically, the conductive posts 216 may provide an electrical path connecting the first redistribution layer 211 with the second redistribution layer 221. The conductive posts 216 may be understood by referring to the description of the conductive posts 116 of FIG. 1.

In some embodiments, the fifth semiconductor package 20 of FIG. 5 may not include a molding layer, separate from the lower molding layer 217, encapsulating the first semiconductor chip 110 and the bonding wires 113.

In some embodiments, the lower molding layer 217 may be disposed on the first redistribution layer 211 and encapsulate the first semiconductor chip 210 and the conductive posts 216. In some embodiments, the lower molding layer 217 disposed on the first redistribution layer 211 may form the lower structure 20_1 by encapsulating the first semiconductor chip 210, the bonding wires 213, and the conductive posts 216. In some embodiments, the lower molding layer 217 may be disposed on the first redistribution layer 211 and surround the first semiconductor chip 210 and the bonding wires 213 in the first direction D1. For example, the lower molding layer 217 may include an epoxy resin, a silicone resin, or a combination thereof.

In some embodiments, the upper structure 20_2 may be disposed on the lower structure 20_1. In some embodiments, the upper structure 20_2 may include a second semiconductor chip 220, a second redistribution layer 221, and a plurality of second bumps 222.

In some embodiments, the second semiconductor chip 220 may be disposed on the second redistribution layer 221. In some embodiments, the second semiconductor chip 220 may be mounted on the second redistribution layer 221 in a flip-chip structure. For example, the second semiconductor chip 220 may have a first surface and a second surface. The first surface may be an active surface and the second surface may be an inactive surface opposite to the first surface. The active surface of the second semiconductor chip 220 may face the second redistribution layer 121.

In some embodiments, the second redistribution layer 221 may be disposed on the first redistribution layer 211. Specifically, the second redistribution layer 221 may be disposed on the lower molding layer 217 disposed on the first redistribution layer 211 and that encapsulates the first semiconductor chip 210, and the like. The second redistribution layer 221 may be further understood by referring to the description of the second redistribution layer 121 of FIG. 1.

In some embodiments, the second redistribution layer 221 may provide an electrical path connecting the second semiconductor chip 220 with the external connection terminals 230. The second redistribution layer 221 may provide an electrical path connecting the second semiconductor chip 220 with the first redistribution layer 211. In some embodiments, a plurality of second bumps 222 may be disposed between the second semiconductor chip 220 and the second redistribution layer 221. The plurality of second bumps 222 may be further understood by referring to the description of the plurality of second bumps 122 of FIG. 1.

In some embodiments, the upper molding layer 223 may be disposed on the second redistribution layer 221 and encapsulate the second semiconductor chip 220 and the plurality of second bumps 222. In some embodiments, the upper molding layer 223 may include a portion for encapsulating the plurality of second bumps 222 between the second semiconductor chip 220 and the second redistribution layer 221. The upper molding layer 223 may be further understood by referring to the description of the upper molding layer 123 of FIG. 1. In some embodiments, the upper molding layer 223 may include the same material as the lower molding layer 217. In some embodiments, the upper molding layer 223 may include a material different from that of the lower molding layer 217.

In some embodiments, the electrical signal of the second semiconductor chip 220 may be transmitted to the second redistribution layer 221 through the plurality of second bumps 222. Thereafter, the electrical signal transmitted to the second redistribution layer 221 may be transmitted to the conductive posts 216 through a plurality of redistribution pads and a plurality of redistribution vias formed in the second redistribution layer 221, and the electrical signal may be transmitted to the first redistribution layer 211 through the conductive posts 216. The electrical signal of the second semiconductor chip 220 transmitted to the first redistribution layer 211 may be transmitted to the external connection terminals 230.

In some embodiments, the external connection terminals 230 may be located on a bottom surface of the first redistribution layer 211 of the lower structure 20_1. The external connection terminals 230 may be further understood by referring to the description of the external connection terminals 130 of FIG. 1.

According to embodiments of the inventive concept, the second semiconductor chip 220 of the upper structure 20_2 may be attached to the second redistribution layer 221 in a flip-chip structure, and the first semiconductor chip 210 of the lower structure 20_1 may be connected to the first redistribution layer 211 through the bonding wires 213. Accordingly, in the second semiconductor package 20 according to embodiments of the inventive concept, a difference in length between a path of the second semiconductor chip 220 of the upper structure 20_2 to the external connection terminals 230 and a path of the first semiconductor chip 210 of the lower structure 20_1 to the external connection terminals 230 may be reduced or eliminated, thereby improving signal characteristics. For example, the path of the second semiconductor chip 220 of the upper structure 20_2 to the external connection terminals 230 and the path of the first semiconductor chip 210 of the lower structure 20_1 to the external connection terminals 230 may be substantially equal. For example, a length of the bonding wires 213, a height of the plurality of second bumps 222, etc., may be configured to reduce a difference in the lengths of electric paths of the fifth semiconductor package 20.

In some embodiments, the first semiconductor chip 210 and/or the second semiconductor chip 220 may include a GDDR (Graphics Double Data Rate) chip. In some embodiments, the first semiconductor chip 210 and the second semiconductor chip 220 may be the same type of semiconductor chip. In some embodiments, the first semiconductor chip 210 and the second semiconductor chip 220 may be different types of semiconductor chips.

Referring to FIG. 6, the sixth semiconductor package 21 may include a lower structure 21_1 and an upper structure 21_2 stacked vertically. Specifically, the upper structure 21_2 may be stacked on the lower structure 21_1 in the second direction D2. The lower structure 21_1 may include the first semiconductor chip 210. The upper structure 21_2 may include the second semiconductor chip 220. Hereinafter, differences from the fifth semiconductor package 20 of FIG. 5 will be mainly described.

In some embodiments, the sixth semiconductor package 21 may further include an underfill layer 224. The underfill layer 224 may be disposed between the second semiconductor chip 220 and the second redistribution layer 221. Specifically, the sixth semiconductor package 21 may further include the underfill layer 224 disposed between the second semiconductor chip 220 and the second redistribution layer 221 of the upper structure 21_2.

In some embodiments, the underfill layer 224 may encapsulate a plurality of second bumps 222 disposed between the second semiconductor chip 220 and the second redistribution layer 221. Specifically, the underfill layer 224 may include a portion disposed between the plurality of second bumps 222 disposed between the second semiconductor chip 220 and the second redistribution layer 221 to encapsulate the plurality of second bumps 222.

The upper molding layer 223 of the sixth semiconductor package 21 of FIG. 6 may not be disposed between the second semiconductor chip 220 and the second redistribution layer 221, and a underfill layer 224, separate from the upper molding layer 223, may be disposed to encapsulate the plurality of second bumps 222. Even when the upper molding layer 223 may contact a portion of a lower surface of the second semiconductor chip 220, for example, around a periphery of an area defined by the plurality of second bumps 222, the underfill layer 224 may encapsulate the plurality of second bumps 222, and the upper molding layer 223 may be disposed on a side surface of the underfill layer 224.

The under filter layer 224 may include, for example, a polymer, an epoxy resin, or a combination thereof. For example, the underfill layer 224 may include a material different from that of the upper molding layer 223.

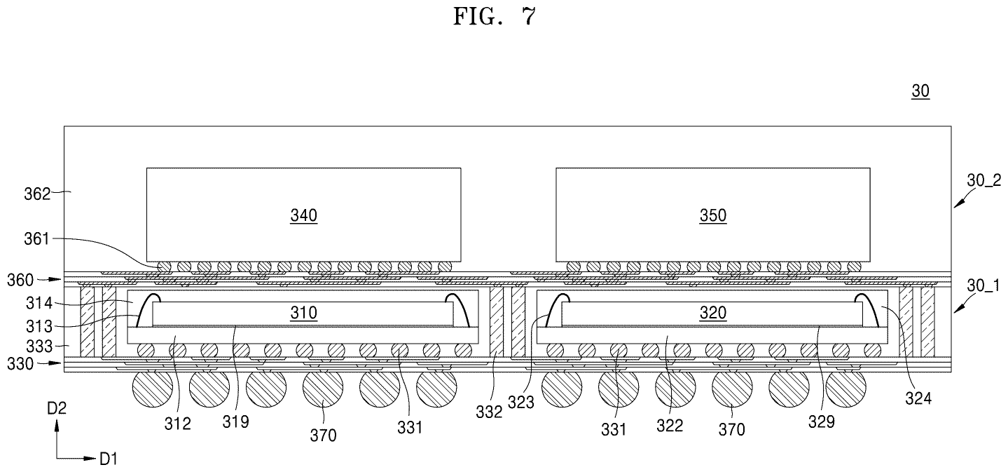

FIG. 7 is a cross-sectional view illustrating a seventh semiconductor package 30 according to an embodiment.

Referring to FIG. 7, the seventh semiconductor package 30 may include a lower structure 30_1 and an upper structure 30_2 stacked vertically. Specifically, the upper structure 30_2 may be stacked on the lower structure 30_1 in the second direction D2. The lower structure 30_1 may include a first semiconductor chip 310 and a second semiconductor chip 320 spaced apart in the first direction D1. The upper structure 30_2 may include a third semiconductor chip 340 and a fourth semiconductor chip 350 spaced apart in the first direction D1.

In some embodiments, the lower structure 30_1 may include the first semiconductor chip 310, the second semiconductor chip 320, a first redistribution layer 330, a first circuit board 312, a second circuit board 322, first bonding wires 313, second bonding wires 323, a plurality of first bumps 331, and conductive posts 332.

In some embodiments, the first semiconductor chip 310 and the second semiconductor chip 320 may be disposed on the first redistribution layer 330. Specifically, the first semiconductor chip 310 may be disposed on the first circuit board 312 and mounted on the first redistribution layer 330. The second semiconductor chip 320 may be disposed on the second circuit board 322 and mounted on the first redistribution layer 330.

In some embodiments, the first redistribution layer 330 may provide an electrical path connecting the first semiconductor chip 310 with the external connection terminals 370 and an electrical path connecting and the second semiconductor chip 320 with the external connection terminals 370. The first redistribution layer 330 may provide an electrical path connecting the first circuit board 312 with the external connection terminals 370, and an electrical path connecting the second circuit board 322 with the external connection terminals 370. The first redistribution layer 330 may be further understood by referring to the description of the first redistribution layer 111 of FIG. 1. The first redistribution layer 330 may include a redistribution layer.

In some embodiments, the first circuit board 312 may be disposed between the first semiconductor chip 310 and the first redistribution layer 330. The first circuit board 312 may provide an electrical path connecting the first semiconductor chip 310 with the first redistribution layer 330. The first circuit board 312 may be a printed circuit board (PCB).

In some embodiments, the second circuit board 322 may be disposed between the second semiconductor chip 320 and the first redistribution layer 330. The second circuit board 322 may provide an electrical path connecting the second semiconductor chip 320 with the first redistribution layer 330. The second circuit board 322 may be a printed circuit board (PCB).

In some embodiments, a first adhesive layer 319 may be disposed between the first semiconductor chip 310 and the circuit board 312. For example, the first semiconductor chip 310 may be attached to the first circuit board 312 by the first adhesive layer 319. In some embodiments, a second adhesive layer 329 may be disposed between the second semiconductor chip 320 and the second circuit board 322. For example, the second semiconductor chip 320 may be attached to the second circuit board 322 by the second adhesive layer 329. In some embodiments, the first adhesive layer 319 and the second adhesive layer 329 may include a die attach film (DAF).

In some embodiments, the first semiconductor chip 310 may be connected to the first circuit board 312 by the first bonding wires 313. Specifically, the first bonding wires 313 may provide an electrical path connecting the first semiconductor chip 310 with the first circuit board 312. For example, the electrical signal generated by the first semiconductor chip 310 may be transmitted to the first circuit board 312 through the first bonding wires 313.

In some embodiments, the second semiconductor chip 320 may be connected to the second circuit board 322 by the second bonding wires 323. Specifically, the second bonding wires 323 may provide an electrical path connecting the second semiconductor chip 320 with the second circuit board 322. For example, the electrical signal generated by the second semiconductor chip 320 may be transmitted to the second circuit board 322 through the second bonding wires 323.

In some embodiments, the first intermediate molding layer 314 may be disposed on the first circuit board 312 and encapsulate the first semiconductor chip 310, the first adhesive layer 319, and the first bonding wires 313. For example, the first intermediate molding layer 314 may include an epoxy resin, a silicone resin, or a combination thereof. The first intermediate molding layer 314 may be further understood by referring to the description of the intermediate molding layer 114 of FIG. 1.

In some embodiments, the second intermediate molding layer 324 may be disposed on the second circuit board 322 and encapsulate the second semiconductor chip 320, the second adhesive layer 329, and the second bonding wires 323. For example, the second intermediate molding layer 324 may include an epoxy resin, a silicone resin, or a combination thereof. The second intermediate molding layer 324 may be further understood by referring to the description of the intermediate molding layer 114 of FIG. 1.

In some embodiments, a first set of the plurality of first bumps 331 may be disposed between the first circuit board 312 and the first redistribution layer 330, and a second set of the plurality of first bumps 331 may be disposed between the second circuit board 322 and the first redistribution layer 330. The first and second sets of the plurality of first bumps 331 may include different bumps of the plurality of first bumps 331. In some embodiments, the plurality of first bumps 331 may be attached to a lower surface of the first circuit board 312 and a lower surface of the second circuit board 322. The plurality of first bumps 331 may provide an electrical path connecting the first circuit board 312 with the first redistribution layer 330, and an electrical path connecting the second circuit board 322 with the first redistribution layer 330. The plurality of first bumps 331 may provide an electrical path connecting the first semiconductor chip 310 with the first redistribution layer 330, and an electrical path connecting the second semiconductor chip 320 with the first redistribution layer 330. The plurality of first bumps 331 may be further understood by referring to the description of the plurality of first bumps 115 of FIG. 1.

In some embodiments, the electrical signal of the first semiconductor chip 310 may be transmitted to the first redistribution layer 330 through the bonding wires 313. Specifically, the electrical signal of the first semiconductor chip 310 may be transmitted to the first circuit board 312 through the first bonding wires 313. Thereafter, the electrical signal transmitted to the first circuit board 312 may be transmitted to the first redistribution layer 330 through the plurality of first bumps 331. The electrical signal of the first semiconductor chip 310 transmitted to the first redistribution layer 330 may be transmitted to the external connection terminals 370 through a plurality of redistribution pads and a plurality of redistribution vias formed in the first redistribution layer 330.

In some embodiments, the electrical signal of the second semiconductor chip 320 may be transmitted to the first redistribution layer 330 through the second bonding wires 323. Specifically, the electrical signal of the second semiconductor chip 320 may be transmitted to the second circuit board 322 through the second bonding wires 323. Thereafter, the electrical signal transmitted to the second circuit board 322 may be transmitted to the first redistribution layer 330 through the plurality of first bumps 331. The electrical signal of the second semiconductor chip 320 transmitted to the first redistribution layer 330 may be transmitted to the external connection terminals 370 through the plurality of redistribution pads and the plurality of redistribution vias formed in the first redistribution layer 330.

In some embodiments, the conductive posts 332 may be disposed between the lower structure 30_1 and the upper structure 30_2. Specifically, the conductive posts 332 may electrically connect the first redistribution layer 330 with the second redistribution layer 360. The conductive posts 332 may be further understood by referring to the description of the conductive posts 116 of FIG. 1.

In some embodiments, the lower molding layer 333 may be formed on the first redistribution layer 330 and encapsulate the first semiconductor chip 310, the second semiconductor chip 320, and the conductive posts 332. Specifically, the lower molding layer 333 may be formed on the first redistribution layer 330 and encapsulate the first intermediate molding layer 314 encapsulating the first semiconductor chip 310, the first adhesive layer 319, the first circuit board 312, and the first bonding wires 313, and the second intermediate molding layer 324 encapsulating the second semiconductor chip 320, the second adhesive layer 329, the second circuit board 322, and the second bonding wires 323, together with the plurality of first bumps 331, and the conductive posts 332. In some embodiments, the lower molding layer 333 may form the lower structure 30_1 by being disposed on the first redistribution layer 330 and encapsulating the first semiconductor chip 310, the first adhesive layer 319, the first circuit board 312, the first bonding wires 313, the second semiconductor chip 320, the second adhesive layer 329, the second circuit board 322, the second bonding wires 323, the plurality of first bumps 331, and the conductive posts 332.

In some embodiments, the lower molding layer 333 may include a portion for encapsulating the plurality of first bumps 331 between the first circuit board 312 and the first redistribution layer 330. Specifically, the lower molding layer 333 may include a portion disposed between each of the plurality of first bumps 331 between the first circuit board 312 and the first redistribution layer 330, thereby encapsulating the plurality of first bumps 331.

In some embodiments, likewise, the lower molding layer 333 may include a portion for encapsulating the plurality of first bumps 331 between the second circuit board 322 and the first redistribution layer 330. Specifically, the lower molding layer 333 may include a portion disposed between the plurality of first bumps 331 between the second circuit board 322 and the first redistribution layer 330, thereby encapsulating the plurality of first bumps 331.

The lower molding layer 333 may include, for example, an epoxy resin, a silicone resin, or a combination thereof. The lower molding layer 333 may be further understood by referring to the description of the lower molding layer 117 of FIG. 1.

In some embodiments, the upper structure 30_2 may be disposed on the lower structure 30_1. In some embodiments, the upper structure 30_2 may include a third semiconductor chip 340 and a fourth semiconductor chip 350 arranged in the first direction D1, a second redistribution layer 360, and a plurality of second bumps 361 arranged in the first direction D1.

In some embodiments, the second redistribution layer 360 may be disposed on the first redistribution layer 330. The second redistribution layer 360 may be further understood by referring to the description of the second redistribution layer 121 of FIG. 1.

In some embodiments, the third semiconductor chip 340 and the fourth semiconductor chip 350 may be disposed on the second redistribution layer 360. In some embodiments, the third semiconductor chip 340 and the fourth semiconductor chip 350 may be mounted on the second redistribution layer 360 in a flip-chip structure.

In some embodiments, the second redistribution layer 360 may provide an electrical path connecting the third semiconductor chip 340 and the fourth semiconductor chip 350 with the external connection terminals 370. The second redistribution layer 360 may provide an electrical path connecting the third semiconductor chip 340 and the fourth semiconductor chip 350 with the first redistribution layer 330.

In some embodiments, a plurality of second bumps 361 may be disposed between the third semiconductor chip 340 and the second redistribution layer 360, and between the fourth semiconductor chip 350 and the second redistribution layer 360. In some embodiments, a first set of the plurality of second bumps 361 may be attached to a lower surface of the third semiconductor chip 340 and a second set of the plurality of second bumps 361 may be attached to a lower surface of the fourth semiconductor chip 350. The first and second sets of the plurality of second bumps 361 may include different bumps of the plurality of second bumps 361. The plurality of second bumps 361 may provide an electrical path connecting the third semiconductor chip 340 with the second redistribution layer 360 and an electrical path connecting the fourth semiconductor chip 350 with the second redistribution layer 360. The plurality of second bumps 361 may be further understood by referring to the description of the plurality of second bumps 122 of FIG. 1.

In some embodiments, the plurality of first bumps 331 and the plurality of second bumps 361 may be of different types of bumps. For example, as described herein, the plurality of first bumps 331 may be attached under the first circuit board 312 and the second circuit board 322, while the plurality of second bumps 361 may be attached under the third semiconductor chip 340 and the fourth semiconductor chip 350.

In some embodiments, size of the plurality of first bumps 331 may be different from the size of the plurality of second bumps 361. Specifically, the width of each of the plurality of first bumps 331 in the first direction D1 may be greater than the width of each of the plurality of second bumps 361 in the first direction D1.

In some embodiments, a pitch between adjacent first bumps of the plurality of first bumps 331 and a pitch between adjacent second bumps of the plurality of second bumps 361 may be different from each other. Specifically, the pitch between adjacent first bumps of the plurality of first bumps 331 in the first direction D1 may be greater than the pitch between adjacent second bumps of the plurality of second bumps 361 in the first direction D1.

In some embodiments, the upper molding layer 362 may be disposed on the second redistribution layer 360 and encapsulate the third semiconductor chip 340, the fourth semiconductor chip 350, and the plurality of second bumps 361. In some embodiments, the upper molding layer 362 may include a portion encapsulating the plurality of second bumps 361 between the third semiconductor chip 340 and the second redistribution layer 360 and between the fourth semiconductor chip 350 and the second redistribution layer 360. Specifically, the upper molding layer 362 may include a portion disposed between the plurality of second bumps 361 between the third semiconductor chip 340 and the second redistribution layer 360, and between the fourth semiconductor chip 350 and the second redistribution layer 360 encapsulating the plurality of second bumps 361. The upper molding layer 362 may be further understood by referring to the description of the upper molding layer 123 of FIG. 1.

In some embodiments, the electrical signal of the third semiconductor chip 340 may be transmitted to the second redistribution layer 360 through the plurality of second bumps 361. Thereafter, the electrical signal transmitted to the second redistribution layer 360 may be transmitted to the conductive posts 332, and may be transmitted to the first redistribution layer 330. The electrical signal of the third semiconductor chip 340 transmitted to the first redistribution layer 330 may be transmitted to the external connection terminals 370.

Likewise, the electrical signal of the fourth semiconductor chip 350 may be transmitted to the second redistribution layer 360 through the plurality of second bumps 361. Thereafter, the electrical signal may be transmitted to the external connection terminals 370 through the conductive posts 332 and the first redistribution layer 330.

In some embodiments, the external connection terminals 370 may be located on a bottom surface of the first redistribution layer 330 of the lower structure 30_1. The external connection terminals 370 may be further understood by referring to the description of the external connection terminals 130 of FIG. 1.

In some embodiments, the first semiconductor chip 310, the second semiconductor chip 320, the third semiconductor chip 340, and the fourth semiconductor chip 350 may include a GDDR chip. In some embodiments, the first semiconductor chip 310 and the second semiconductor chip 320 may be the same type of semiconductor chip. The third semiconductor chip 340 and the fourth semiconductor chip 350 may be the same type of semiconductor chip. In some embodiments, the first semiconductor chip 310 and the third semiconductor chip 340 may be the same type of semiconductor chip. The second semiconductor chip 320 and the fourth semiconductor chip 350 may be the same type of semiconductor chip. In some embodiments, the first semiconductor chip 310 and the third semiconductor chip 340 may be different types of semiconductor chips. The second semiconductor chip 320 and the fourth semiconductor chip 350 may be the different types of semiconductor chips.

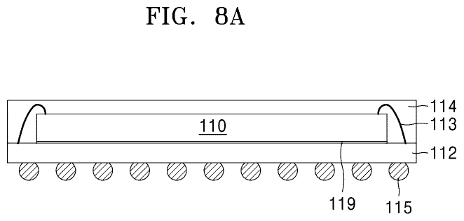

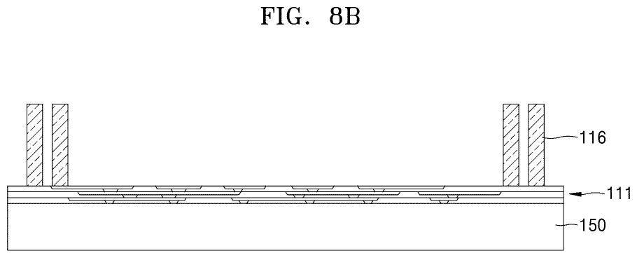

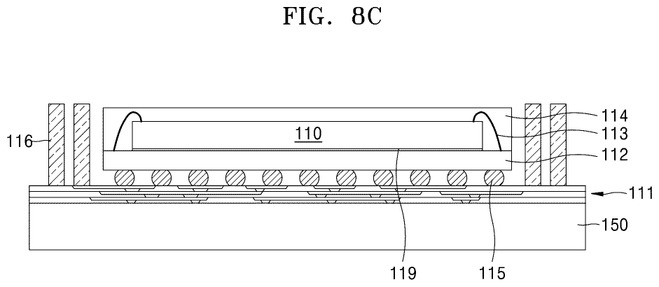

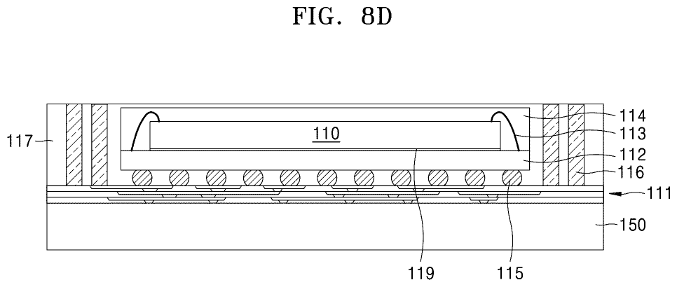

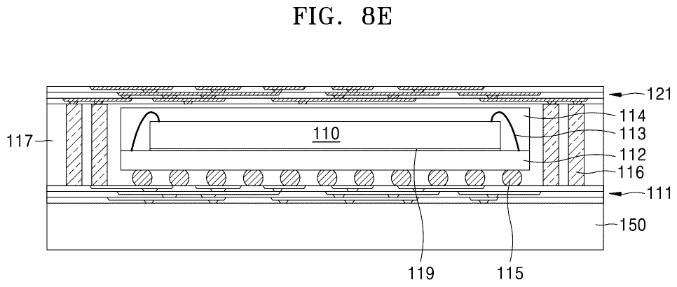

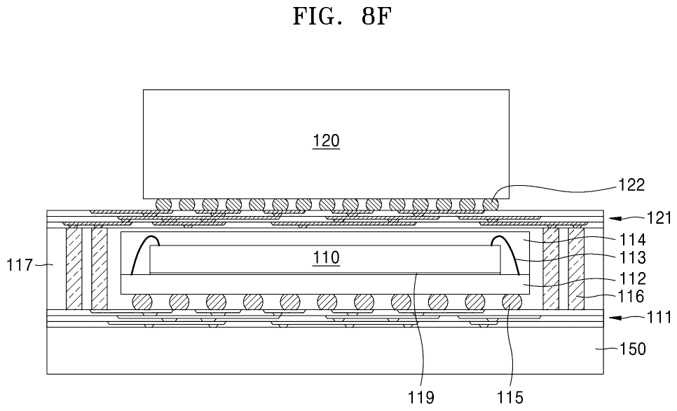

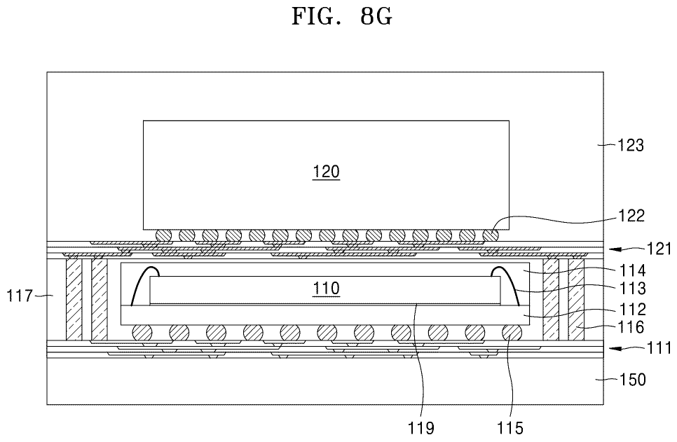

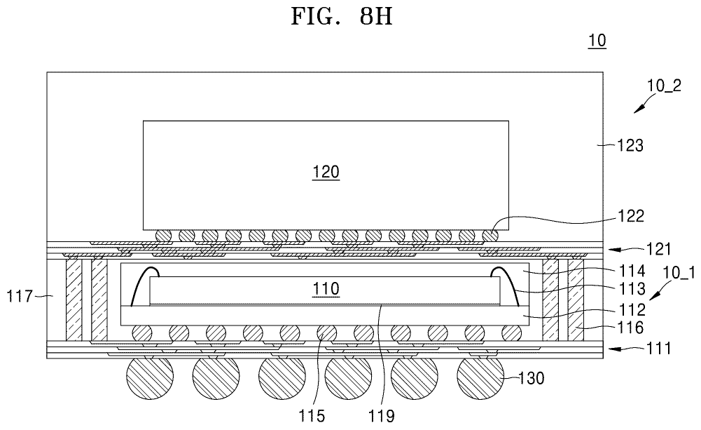

FIGS. 8A to 8H are cross-sectional views for explaining a method of manufacturing a semiconductor package 10 according to some embodiments. Specifically, FIGS. 8A to 8H are cross-sectional views illustrating a method of manufacturing the semiconductor package 10 described with reference to FIG. 1.

Referring to FIG. 8A, the first semiconductor chip 110 may be provided. Specifically, the first semiconductor chip 110 may be attached to the circuit board 112 by using the adhesive layer 119, and the bonding wires 113 connecting the first semiconductor chip 110 with the circuit board 112 may be formed. Subsequently, an intermediate molding layer 114 for encapsulating the first semiconductor chip 110, the adhesive layer 119, the circuit board 112, and the bonding wires 113 may be formed. Thereafter, the plurality of first bumps 115 may be disposed on the bottom surface of the circuit board 112.

Referring to FIG. 8B, the first redistribution layer 111 may be disposed on a carrier substrate 150. Subsequently, the conductive posts 116 may be disposed on the first redistribution layer 111.

Referring to FIG. 8C, the first semiconductor chip 110 provided with reference to FIG. 8A may be disposed on the carrier substrate 150 on which the first redistribution layer 111 and the conductive posts 116 are formed. Specifically, the first semiconductor chip 110 may be mounted such that the plurality of first bumps 115 are disposed on the first redistribution layer 111. As a result, the first bumps 115 and the conductive posts 116 may be disposed on the first redistribution layer 111, and the circuit board 112 and the first semiconductor chip 110 may be disposed on the first bumps 115.

Referring to FIG. 8D, a lower molding layer 117 may be disposed on the first redistribution layer 111 and may encapsulate the first semiconductor chip 110 and the conductive posts 116. Specifically, the lower molding layer 117 may be disposed on the first redistribution layer 111 and encapsulate the intermediate molding layer 114 disposed on the circuit board 112 and encapsulating the first semiconductor chip 110, the adhesive layer 119, and the bonding wires 113 together with the plurality of first bumps 115, and the conductive posts 116. Here, the lower molding layer 117 may include a portion disposed between the circuit board 112 and the first redistribution layer 111 to encapsulate the plurality of first bumps 115.

In some embodiments, a process of forming the lower molding layer 117 may include a process of planarizing a molding layer after forming the molding layer on the first redistribution layer 111 and encapsulating the first semiconductor chip 110 and the conductive posts 116. Specifically, a portion of the molding layer formed on the conductive posts 116 may be removed and upper surfaces of the conductive posts 116 may be exposed. For example, a process of removing a portion of the molding layer may include a process of grinding a portion of the molding layer.

Referring to FIG. 8E, the second redistribution layer 121 may be disposed on the lower molding layer 117. Specifically, the second redistribution layer 121 may be disposed to be connected to the conductive posts 116 exposed by the lower molding layer 117.

Referring to FIG. 8F, the plurality of second bumps 122 and the second semiconductor chip 120 may be disposed on the second redistribution layer 121. The second semiconductor chip 120 may be mounted on the second redistribution layer 121 by using the plurality of second bumps 122. For example, the second semiconductor chip 120 may be mounted on the second redistribution layer 121 in a flip-chip structure. The second semiconductor chip 120 may be connected to the second redistribution layer 121 by the plurality of second bumps 122.

Referring to FIG. 8G, the upper molding layer 123 may be formed on the second redistribution layer 121 for encapsulating the second semiconductor chip 120 and the plurality of second bumps 122. In some embodiments, a process of forming the upper molding layer 123 may include a process of planarizing a molding layer after forming the molding layer on the second redistribution layer 121 for encapsulating the second semiconductor chip 120 and the plurality of second bumps 122. In this case, the upper molding layer 123 may include a portion disposed between the second semiconductor chip 120 and the second redistribution layer 121 to encapsulate the plurality of second bumps 122.

Referring to FIG. 8H, the carrier substrate 150 may be removed, and the plurality of external connection terminals 130 may be formed under the first redistribution layer 111. As a result, the semiconductor package 10 may be manufactured.

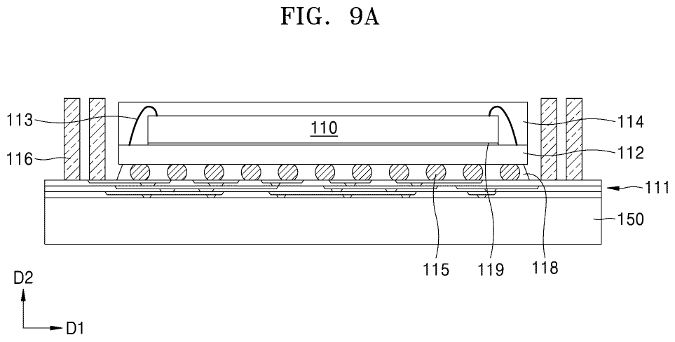

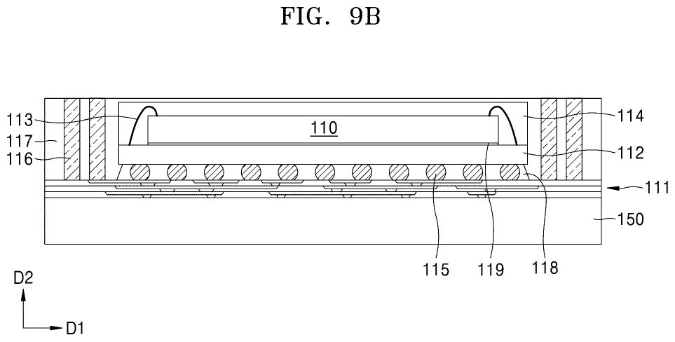

FIG. 9A and FIG. 9B are cross-sectional views for explaining a method of manufacturing a semiconductor package according to some embodiments. Specifically, FIG. 9A and FIG. 9B are cross-sectional views showing a process following FIG. 8C to explain a manufacturing method of the second semiconductor package 11 described with reference to FIG. 2.

Referring to FIG. 9A, the first underfill layer 118 for encapsulating the plurality of first bumps 115 may be formed between the circuit board 112 and the first redistribution layer 111.

Referring to FIG. 9B, the lower molding layer 117 may be disposed on the first redistribution layer 111 for encapsulating the first semiconductor chip 110 and the conductive posts 116. Specifically, the lower molding layer 117 may be disposed on the first redistribution layer 111 to encapsulate the intermediate molding layer 114 molding the first semiconductor chip 110, the adhesive layer 119, the circuit board 112, and the bonding wires 113 together with the first underfill layer 118, and the conductive posts 116. Here, the lower molding layer 117 may include a portion disposed between the circuit board 112 and the first redistribution layer 111 to encapsulate the plurality of first bumps 115.

Subsequently, the second semiconductor package 11 of FIG. 2 may be manufactured by performing a subsequent process.

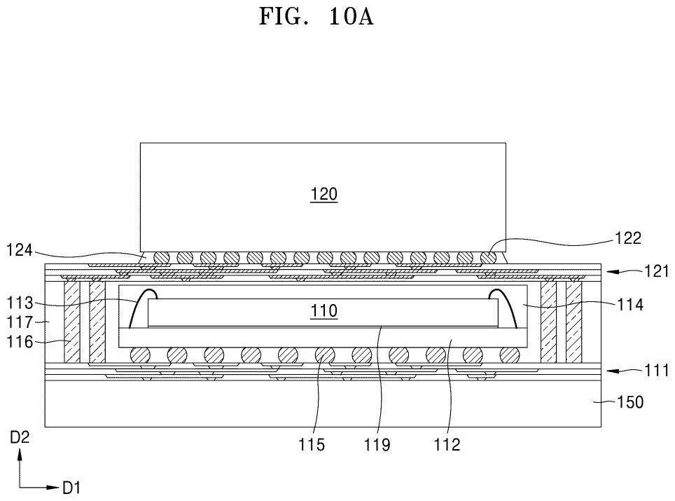

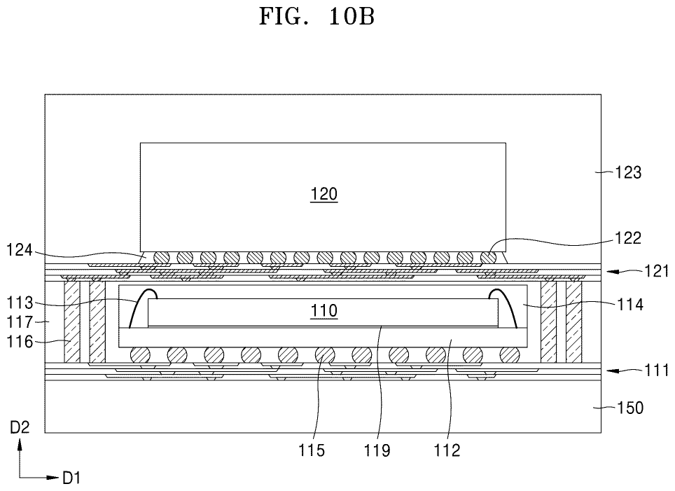

FIG. 10A and FIG. 10B are cross-sectional views for explaining a method of manufacturing semiconductor packages according to some embodiments. Specifically, FIG. 10A and FIG. 10B are cross-sectional views showing a process following FIG. 8F to explain a manufacturing method of the third semiconductor package 12 described with reference to FIG. 3.

Referring to FIG. 10A, the second underfill layer 124 for encapsulating the plurality of second bumps 122 may be formed between the second semiconductor chip 120 and the second redistribution layer 121.

Referring to FIG. 10B, the upper molding layer 123 disposed on the second redistribution layer 121 for encapsulating the second semiconductor chip 120 and the second underfill layer 124. Specifically, the upper molding layer 123 may be formed to encapsulate the second underfill layer 124 encapsulating the plurality of second bumps 122 together with the second semiconductor chip 120 and the second redistribution layer 121. In this case, the upper molding layer 123 may not include a portion disposed between the second semiconductor chip 120 and the second redistribution layer 121 to encapsulate the plurality of second bumps 122.

Subsequently, the third semiconductor package 12 of FIG. 3 may be manufactured by performing a subsequent process.

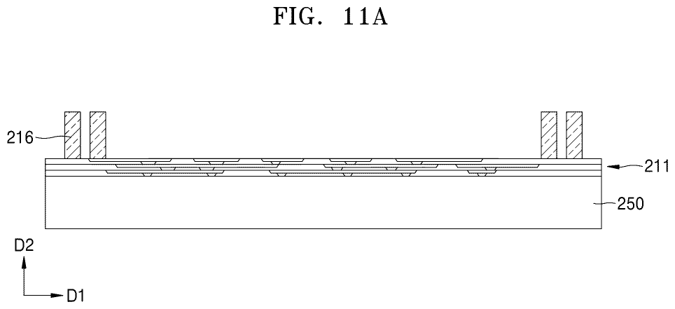

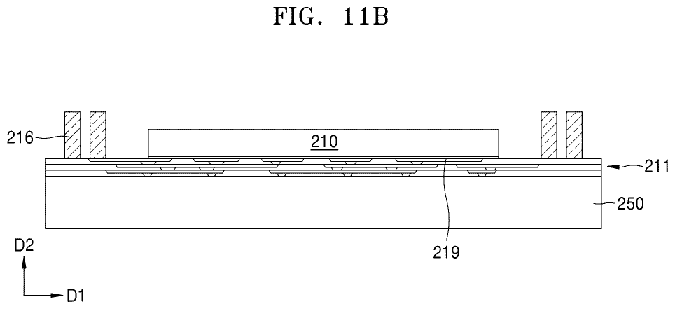

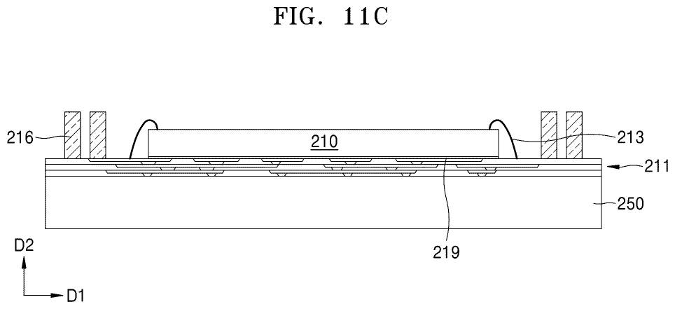

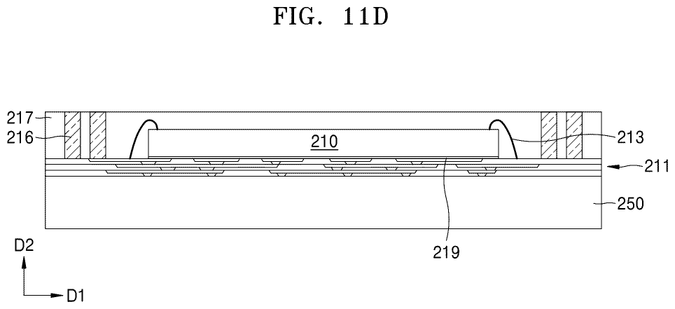

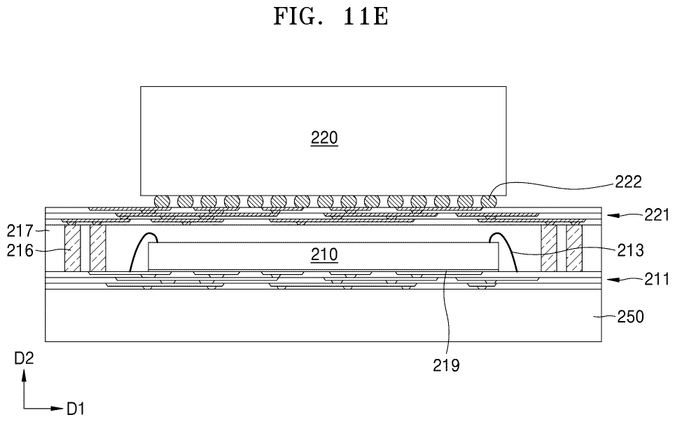

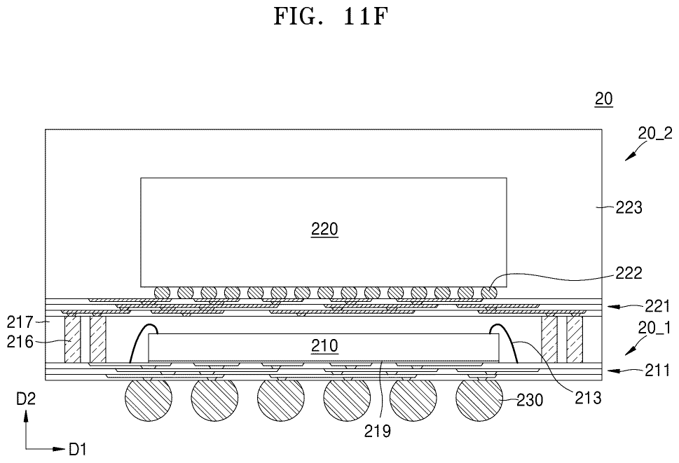

FIGS. 11A to 11F are cross-sectional views for explaining a method of manufacturing the fifth semiconductor package 20 according to some embodiments. Specifically, FIGS. 11A to 11F are cross-sectional views illustrating a method of manufacturing the fifth semiconductor package 20 described with reference to FIG. 5.

Referring to FIG. 11A, the first redistribution layer 211 may be disposed on the carrier substrate 250. Subsequently, the conductive posts 216 may be formed on the first redistribution layer 211.

Referring to FIG. 11B, the first semiconductor chip 210 may be disposed on the carrier substrate 150 on which the first redistribution layer 211 and the conductive posts 216 are formed. Specifically, the first semiconductor chip 210 may be attached to the first redistribution layer 211 by using the adhesive layer 219. For example, the first semiconductor chip 210 may be disposed between the plurality of conductive posts 216.

Referring to FIG. 11C, the bonding wires 213 connecting the first semiconductor chip 210 to the first redistribution layer 211 may be formed. The bonding wires 213 may be connected to an upper surface, which may be an active surface, of the first semiconductor chip 210.

Referring to FIG. 11D, the lower molding layer 217 may be disposed on the first redistribution layer 211 for encapsulating the first semiconductor chip 210, the bonding wires 213, and the conductive posts 216.

In some embodiments, a process of forming the lower molding layer 217 may include a process of planarizing a molding layer after forming the molding layer for encapsulating the first semiconductor chip 210, the bonding wires 213, and the conductive posts 216. Specifically, a portion of the molding layer formed on the conductive posts 216 may be removed to expose the upper surface of the conductive posts 216. For example, a process of removing a portion of the molding layer may include a process of grinding a portion of the molding layer.

Referring to FIG. 11E, the second redistribution layer 221 may be disposed on the lower molding layer 217. Specifically, the second redistribution layer 221 may be disposed to be connected to the conductive posts 116 exposed by the lower molding layer 217.

Subsequently, the plurality of second bumps 222 and the second semiconductor chip 220 may be disposed on the second redistribution layer 221. The second semiconductor chip 220 may be disposed on the second redistribution layer 221 by using the plurality of second bumps 222. For example, the second semiconductor chip 220 may be mounted on the second redistribution layer 221 in a flip-chip structure. The second semiconductor chip 220 may be connected to the second redistribution layer 221 by the plurality of second bumps 222.

Referring to FIG. 11F, the upper molding layer 223 may be disposed on the second redistribution layer 221 for encapsulating the second semiconductor chip 220 and the plurality of second bumps 222. In some embodiments, a process of forming the upper molding layer 223 may include a process of planarizing a molding layer after forming the molding layer on the second redistribution layer 221 for encapsulating the second semiconductor chip 220 and the plurality of second bumps 222. In this case, the upper molding layer 223 may include a portion disposed between the second semiconductor chip 220 and the second redistribution layer 221 to encapsulate the plurality of second bumps 122.

Subsequently, the carrier substrate 250 may be removed, and the plurality of external connection terminals 230 may be formed under the first redistribution layer 211. As a result, the fifth semiconductor package 20 may be manufactured.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first redistribution layer;
a first semiconductor chip disposed on the first redistribution layer;
a circuit board disposed between the first redistribution layer and the first semiconductor chip;
a plurality of bonding wires connecting the first semiconductor chip and the circuit board to each other;
a second redistribution layer disposed on the first semiconductor chip;
a second semiconductor chip disposed on the second redistribution layer; and
a plurality of conductive posts connecting the first redistribution layer and the second redistribution layer to each other.

2. The semiconductor package of claim 1, further comprising a plurality of external connection terminals disposed under the first redistribution layer,
wherein the second semiconductor chip is disposed on the second redistribution layer, in a flip-chip structure.

3. The semiconductor package of claim 1, further comprising a plurality of first bumps disposed between the circuit board and the first redistribution layer,
wherein the plurality of bonding wires electrically connect an upper surface of the first semiconductor chip and an upper surface of the circuit board.

4. The semiconductor package of claim 3, further comprising a plurality of second bumps disposed between the second semiconductor chip and the second redistribution layer.

5. The semiconductor package of claim 4, wherein size of each of the plurality of first bumps are greater than size of each of the plurality of second bumps.

6. The semiconductor package of claim 1, further comprising a molding layer disposed on the circuit board and encapsulating the first semiconductor chip and the plurality of bonding wires.

7. The semiconductor package of claim 1, further comprising a molding layer disposed on the first redistribution layer and encapsulating the first semiconductor chip and the plurality of conductive posts.

8. The semiconductor package of claim 7, further comprising a plurality of first bumps disposed between the circuit board and the first redistribution layer, wherein the molding layer comprises a portion for encapsulating the plurality of first bumps.

9. The semiconductor package of claim 7, further comprising:
a plurality of first bumps disposed between the circuit board and the first redistribution layer; and
an underfill layer disposed between the circuit board and the first redistribution layer and encapsulating the plurality of first bumps.

10. The semiconductor package of claim 1, further comprising a molding layer disposed on the second redistribution layer and encapsulating the second semiconductor chip.

11. A semiconductor package comprising:
a lower structure;
an upper structure stacked on the lower structure; and
a plurality of external connection terminals disposed under the lower structure,
wherein the lower structure comprises:
a first redistribution layer;
a first semiconductor chip disposed on the first redistribution layer;
a plurality of bonding wires connecting the first semiconductor chip and the first redistribution layer to each other; and
a plurality of conductive posts connecting the first redistribution layer and the upper structure to each other,
wherein the upper structure comprises:
a second redistribution layer disposed on the lower structure;
a second semiconductor chip disposed on the second redistribution layer; and
a plurality of bumps disposed between the second semiconductor chip and the second redistribution layer.

12. The semiconductor package of claim 11, wherein the lower structure further comprises an adhesive layer disposed between the first semiconductor chip and the first redistribution layer, wherein the adhesive layer is in contact with an upper surface of the first redistribution layer.

13. The semiconductor package of claim 11, wherein the second semiconductor chip is disposed on the second redistribution layer, in a flip-chip structure.

14. The semiconductor package of claim 11, wherein the first semiconductor chip and the second semiconductor chip comprise a graphics double data rate (GDDR) chip.

15. The semiconductor package of claim 11, wherein
the lower structure further comprises a lower molding layer disposed on the first redistribution layer and encapsulating the first semiconductor chip, the plurality of bonding wires, and the plurality of conductive posts, and
the upper structure further comprises an upper molding layer disposed on the second redistribution layer and encapsulating the second semiconductor chip.

16. The semiconductor package of claim 15, wherein the upper structure further comprises an underfill layer disposed between the second semiconductor chip and the second redistribution layer and encapsulating the plurality of bumps.

17. A semiconductor package comprising:
a first redistribution layer;
a first semiconductor chip and a second semiconductor chip, spaced apart from each other in a first direction on the first redistribution layer;
a first circuit board disposed between the first redistribution layer and the first semiconductor chip;
a second circuit board disposed between the first redistribution layer and the second semiconductor chip;
first bonding wires connecting the first semiconductor chip and the first circuit board to each other;
second bonding wires connecting the second semiconductor chip and the second circuit board to each other;
a plurality of first bumps disposed on the first redistribution layer, wherein the first circuit board is disposed on a first set of the plurality of first bumps and the second circuit board is disposed on a second set of the plurality of first bumps;
a second redistribution layer disposed on the first semiconductor chip;
a third semiconductor chip and a fourth semiconductor chip, spaced apart from each other in the first direction on the second redistribution layer;
a plurality of second bumps disposed on the second redistribution layer, wherein the third semiconductor chip is disposed on a first set of the plurality of second bumps and the fourth semiconductor chip is disposed on a second set of the plurality of second bumps;
a plurality of conductive posts connecting the first redistribution layer and the second redistribution layer to each other; and
a plurality of external connection terminals disposed under the first redistribution layer,
wherein the first semiconductor chip is connected to the first redistribution layer through the first bonding wires and the first circuit board, and
the third semiconductor chip is attached to the second redistribution layer, in a flip-chip structure.

18. The semiconductor package of claim 17, wherein
an electrical signal of the second semiconductor chip is transmitted to the first redistribution layer through the second bonding wires and the second circuit board, and
an electrical signal of the fourth semiconductor chip is transmitted to the second redistribution layer through the plurality of second bumps.

19. The semiconductor package of claim 17, wherein a pitch between the plurality of first bumps is greater than a pitch between the plurality of second bumps.

20. The semiconductor package of claim 17, further comprising:
a first intermediate molding layer disposed on the first circuit board and encapsulating the first semiconductor chip and the first bonding wires;
a second intermediate molding layer disposed on the second circuit board and encapsulating the second semiconductor chip and the second bonding wires;
a lower molding layer disposed on the first redistribution layer and encapsulating the first intermediate molding layer, the second intermediate molding layer, the plurality of first bumps, and the plurality of conductive posts; and
an upper molding layer disposed on the second redistribution layer and encapsulating the third semiconductor chip, the fourth semiconductor chip, and the plurality of second bumps.
